(19) United States
(12) Patent Application Publication
(10) Pub. No.: US 2003/0199140 A1
(43) Pub. Date: Oct. 23, 2003

(54) Method of manufacturing semiconductor device

(75) Inventor: Tamotsu Ogata, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/274,109

(22) Filed: Oct. 21, 2002

(30) Foreign Application Priority Data
Apr. 19, 2002 (JP) 2002-117915 (P)

(51) Int. Cl. H01L 21/8242; H01L 21/311

(52) U.S. Cl. 438/241; 438/981

(57) ABSTRACT

A thin gate insulating film of a transistor in a core circuit region is formed with a three-layer structure having an oxide film formed by thermally oxidizing a main surface of a semiconductor substrate (silicon substrate), a CVD nitride film formed on the oxide film and oxynitride film formed by oxidizing the upper surface of the CVD oxide film. A thick gate insulating film of a transistor in an I/O circuit region is formed with a pure oxide film. As a result, such a semiconductor device is obtained in that NBTI of the transistor in the I/O circuit region can be reduced, reliability of the gate insulating film can be improved while a threshold voltage of the transistor in the core circuit region can be properly controlled, and NBTI of the transistor in the core circuit region can be reduced.

### BACKGROUND OF THE INVENTION

1. Field of the Invention

The present invention relates to a method of manufacturing a semiconductor device including a thin gate insulating film for a transistor included in a first circuit region and a thick gate insulating film for a transistor included in a second circuit region.

2. Description of the Background Art

Conventionally, logic circuits and semiconductor devices merged with logic circuits and DRAM (Dynamic Random Access Memory) circuits, that is, system LSI (Large Scale Integration), so-called embedded DRAM (referred to as “e RAM” hereinafter) have been manufactured. A method of manufacturing such a logic circuit will partially be described below.

The logic circuit employs two kinds of gate insulating films including a thin gate insulating film for use in a transistor in a first circuit region and a thick gate insulating film for use in a transistor in a second circuit region.

By way of illustration, the first circuit region may be a core circuit region and the second circuit region may be a region including a input/output circuit and an analog circuit (referred to as “I/O circuit region” hereinafter), for the purpose of description of the conventional technique.

Since the transistor in I/O circuit region as an exemplary second circuit region is driven with a supply voltage, for example, of about 3.3 V, it employs a gate insulating film having a thickness larger than that of the transistor in the core circuit region as an exemplary first circuit region driven with a supply voltage of about 1.5 V. A dual oxide process is used in order to form these two kinds of gate insulating films on the same wafer. The dual oxide process will be described below.

In the conventional dual oxide process, as shown in FIG. 11, in the core circuit region, an isolation insulating film 101 is first formed as an element isolating region to surround an element forming region (active region) of semiconductor substrate 100. On the other hand, in the I/O circuit region, an isolation insulating film 110 is formed as an element isolating region to surround an element forming region (active region) of semiconductor substrate 100.

Then, an underlying oxide film 102 is formed in the active region of the core circuit region and an underlying oxide film 112 is formed in the active region of the I/O circuit region.

Then, ion implantation is performed on underlying oxide film 102 in the active region of the core circuit region and on underlying oxide film 112 in the active region of the I/O circuit region. Accordingly, a channel region in the core circuit region and a channel region in the I/O region are formed while threshold voltages for the respective completed transistors in the core and I/O circuit regions are controlled.

Then, underlying oxide films 102 and 112 in the core and I/O circuit regions are removed along with the surfaces of element isolation insulating films 101 and 110. Thereafter, the surfaces of the active regions in the core and I/O circuit regions are properly cleaned. Then, as shown in FIG. 12, a thermal oxide film 103 is formed in the active region of the core circuit region and a thermal oxide film 113 is formed in the active region of the I/O circuit region.

Photolithography is then performed as shown in FIG. 13. Only the active region of the I/O circuit region is covered with photoresist film 116. Using photoresist film 116 as a mask, thermal oxide film 103 formed in the core circuit region is etched using hydrogen fluoride so that only thermal oxide film 113 formed in the I/O circuit region is left.

Then, as shown in FIG. 14, a proper cleaning is performed on the active region of the core circuit region. Thereafter, in the core circuit region, a thin gate insulating film is formed which has a thickness smaller than that of the thick gate insulating film to be formed in the I/O circuit region described later. At this point, for the reason described later, the thin gate insulating film employs an oxynitride film 1045 including a layer 104 with a high concentration of nitrogen and a layer 105 with a high concentration of oxide.

Furthermore, as shown in FIG. 14, in the I/O circuit region, oxynitride film 1045 to form the thin gate insulating film is formed in lower side portion thermal oxide film 113 initially formed. Therefore, a stacked gate insulating film 1345 is formed in which nitrogen included in oxynitride film 1045 segregates (nitrogen locally exists more) in the vicinity of the active region.

After a polysilicon film is deposited on each of the active regions of the core region and the I/O circuit region, using photolithography and dry-etching, a gate electrode 107 is formed on the active region of the core circuit region and a gate electrode 117 is formed on the active region of the I/O circuit region. Accordingly, as shown in FIG. 15, a dual gate structure is formed in which an N-type gate electrode is formed in an N-channel transistor and a P-type gate electrode is formed in a P-channel transistor. It is noted that the N-type and P-type gate electrodes are formed by ion implantation of N-type and P-type dopants when source/drain regions are formed in the transistors in the active region of the core circuit region and in the active region of the I/O circuit region.

Since some impurities as dopants (for example boron as a P-type dopant) have a large diffusion coefficient in a thermal oxide film, so-called penetration may occur, that is, an impurity in the gate electrode may pass through the gate insulating film and penetrate into the silicon substrate as semiconductor substrate 100 by thermal diffusion in thermal process step after impurity implantation. Penetration of impurity such as boron into the gate insulating film is conspicuous when the gate insulating film is thinner and thus it causes a problem especially in the transistor in the core circuit region having a thin gate insulating film. Since penetration of boron causes variations in a threshold voltage of the transistor and reduced reliability of the gate insulating film, penetration of boron has to be minimized.

In this respect, as shown in FIG. 14, it is reported that penetration of boron can be prevented by forming oxynitride film 1045, for example, by nitrifying the thermal oxide film using NO or N₂O gas at the time of forming the thin gate insulating film.

When the thickness of the thin gate insulating film (oxynitride film 1045) is further reduced to attain higher performance of the transistor, the proportion of nitrogen in the thin gate insulating film needs to be increased because of the impurity penetration. More specifically, oxynitride film 1045 with a high concentration of nitrogen has to be formed as a thin gate insulating film.

When the proportion of nitrogen concentration in the gate insulating film is increased, however, NBTI (Negative Bias Temperature Stress Instability) is disadvantageously increased in the P-type transistor. In other words, under a certain bias and a certain temperature stress, the property such as a transistor threshold voltage, drain current and the like may deviate from a designed value.

This problem is outstanding in the transistor in the I/O circuit using stacked gate insulating film 1345 as a thick gate insulating film. Nitrification process is performed when oxynitride film 1045 is formed as a thin gate insulating film in the core circuit region. At that time, nitrification is also effected on stacked gate insulating film 1345 as a thick gate insulating film in the I/O circuit region formed by additionally applying oxynitride film 1045 onto thermal oxide film 113, so that NBTI for the transistor having the thick gate insulating film is increased.

In order to reduce NBTI, it is necessary to reduce a concentration of nitrogen in the vicinity of the interface between the gate insulating film and the channel region. There is a trade-off between prevention of boron penetration and reduction of nitrogen concentration in the vicinity of the interface between the gate insulating film and the channel region. Therefore, what is required is a method of manufacturing a semiconductor device that achieves both prevention of boron penetration in the transistor in the core circuit region and reduction of NBTI in the transistor in the I/O circuit region.

### SUMMARY OF THE INVENTION

An object of the present invention is to provide a method of manufacturing a semiconductor device that attains reduction of NBTI of a transistor in a second circuit region, improved reliability of a gate insulating film with a proper control of a threshold voltage of a transistor in a first region, and reduction of NBTI of a transistor in the first circuit region.

The present invention provides a method of manufacturing a semiconductor device including a dual oxide process by which a thin gate insulating film for a transistor included in a first circuit region and a thick gate insulating film for a transistor in a second circuit region having a thickness larger than the thin gate insulating film are formed on the same semiconductor substrate (wafer). In accordance with the method of manufacturing a semiconductor device, in the first circuit region, a transistor is formed including a thin gate insulating film having a two-layer structure stacked with an oxide film below and a CVD (Chemical Vapor Deposition) nitride film above, and in the second region, a transistor is formed including a thick gate insulating film having a drive voltage higher than that of the transistor in the first circuit region and having a pure oxide film with a thickness larger than that of the thin gate insulating film.

According above described method, NBTI of a transistor in a second circuit region is reduced, reliability of a gate insulating film with a proper control of a threshold voltage of a transistor in a first region is improved, and NBTI of a transistor in the first circuit region is reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a structure of a semiconductor device in accordance with a first embodiment.

FIGS. 2 to 5 are views illustrating a method of manufacturing a semiconductor device in accordance with the first embodiment.

FIGS. 6 to 10 are views illustrating the method of manufacturing a semiconductor device in accordance with a second embodiment.

FIGS. 11 to 15 are views illustrating a conventional method of manufacturing a semiconductor device.

### DESCRIPTION OF THE PREFERRED EMBODIMENTS

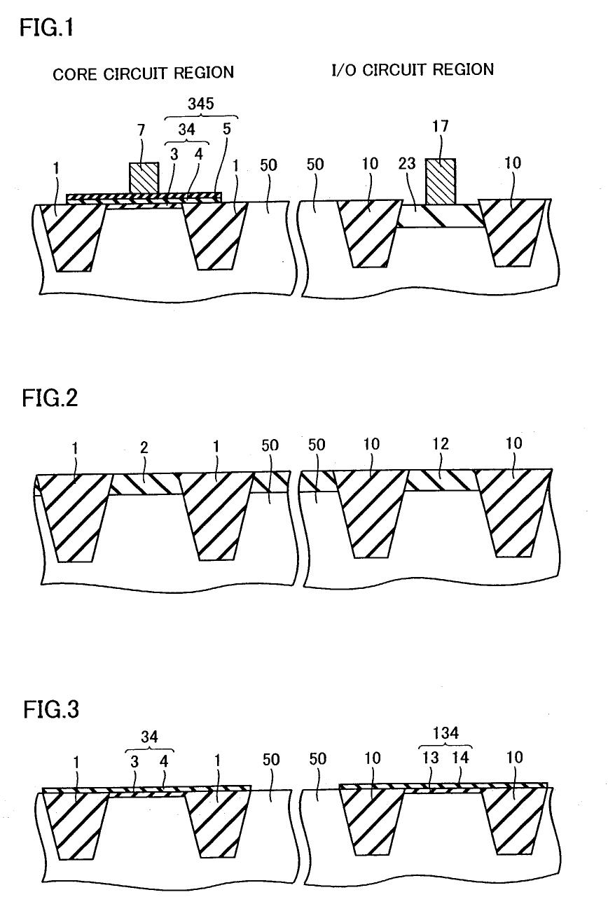

In the following, a semiconductor device and a method of manufacturing the same in accordance with embodiments of the present invention will be described with reference to FIGS. 1 to 10.

(First Embodiment)

Referring to FIGS. 1 to 5, a semiconductor device and a method of manufacturing the same in accordance with the present embodiment will be described. It is noted that the semiconductor device in the present embodiment specifically includes a logic circuit and a so-called embedded DRAM merged with a logic circuit and a DRAM circuit.

First, the structure of the semiconductor device in the present embodiment will be described with reference to FIG. 1. The semiconductor device in the present embodiment includes, as shown in FIG. 1, a transistor with a core circuit region as an exemplary first circuit region of the invention formed with a thin gate insulating film of a three-layer structure 345 having an oxide film 3 formed by thermally oxidizing a main surface of a semiconductor substrate (silicon substrate), a CVD nitride film 4 formed on oxide film 3 and an oxynitride film 5 formed by oxidizing the upper surface of the CVD nitride film. It is noted that oxide film 3 may be formed by depositing gas including oxide such as by CVD. CVD nitride film 4 is formed by gradually depositing gas including nitrogen on oxide film 3 using a so-called CVD process.

The semiconductor device in the present embodiment further includes a transistor with an I/O circuit region as an exemplary second circuit region of the invention having a thick gate insulating film formed by pure oxide film 23, as shown in FIG. 1.

Because of the structure described above, the thick gate insulating film of the transistor in the I/O circuit is pure oxide film 23, that is, not nitrified, so that NBTI can be reduced.

Since the thin gate insulating film of the transistor in the core circuit region has three-layer structure 345 having oxide film 3, CVD 4 and oxynitride film 5, more specifically since CVD nitride film 4 is sandwiched between oxide film 3 and oxynitride film 5, boron is prevented from penetrating the thin gate insulating film in boron implantation process into the source/drain region. Accordingly, the threshold voltage of the transistor in the core circuit is readily controlled and in addition reliability of the thin gate insulating film is improved.

Furthermore, since oxide film 3 is provided between nitride film 4 and the channel region, specifically since a concentration of nitrogen is low in the vicinity of the interface between the gate insulating film and the channel region, NBTI of the transistor in the core circuit region can be reduced.

In order to illustrate the effect obtained from the structure of the semiconductor device in the present embodiment more specifically, a semiconductor device as a comparative example is provided in which a thin gate insulating film having a two-layer structure corresponding to that of oxide film 3 and CVD nitride film 4 is formed by thermally nitrifying the upper surface of the oxide film. The thin gate insulating film having the two-layer structure of the oxide film and the oxynitride film in the semiconductor device of this comparative example may suffer nitrogen segregation not only on the upper surface of the oxide film but also in the vicinity of the interface between the active region and the oxide film, because of thermal nitrification. In the two-layer structure having oxide film 3 and CVD nitride film 4 in the semiconductor device in the present embodiment, CVD nitride film 4 is formed by gradually depositing gas including nitrogen on oxide film 3 using the action of CVD, rather than by binding nitrogen on the upper surface of the oxide film using thermal energy as in the thermal nitrification of the upper surface of oxide film 3. Therefore, the amount of nitrogen of CVD nitride film 4 diffusing into the oxide film is significantly small. As a result, it is less likely that nitrogen segregates also in the vicinity of the interface between the active region and oxide film 3. Therefore, it is possible to further ensure that NBTI is reduced in the transistor in the first circuit region.

A dual gate process for use in a method of manufacturing a logic circuit of the semiconductor device in the present embodiment will be described.

As shown in FIG. 2, in the dual oxide process in the present embodiment, first, in the core circuit region, an isolation insulating film 1 is formed as an element isolating region to surround semiconductor substrate 50 as an active region. On the other hand, in the I/O region, an isolation insulating film 10 is formed as an element isolating region to surround the semiconductor substrate 50 as an active region. Then, an underlying oxide film 2 is formed in the active region in the core circuit region and an underlying oxide film 12 is formed in the active region in the I/O region.

Thereafter, ion implantation is performed respectively on underlying oxide film 2 in the active region in the core circuit region and underlying oxide film 12 in the active region in the I/O region, so that the channel regions are respectively formed in the core and I/O circuit regions while the threshold voltages of the completed transistors in the core and I/O circuit regions are controlled.

Then, as shown in FIG. 3, underlying oxide film 2 in the core circuit region and underlying oxide film 12 in the I/O circuit region are removed along with the upper surfaces of element isolation insulating films 1 and 10. Thereafter, the active regions in the core and I/O circuit regions are properly cleaned. Then, by oxidizing the silicon substrate as an example of semiconductor substrate 50 or by CVD using gas derived from SiH₂Cl₂ and N₂O, an oxide film 3 is formed in the active region in the core circuit region and an oxide film 13 is formed in the active region in the I/O circuit region.

After forming oxide films 3 and 13, CVD nitride film 4 is deposited on the oxide film and CVD nitride film 14 is deposited on oxide film 13, for example, by CVD using gas derived from SiH₂Cl₂ and NH₃. Accordingly, a thin two-layer stack structure 34 with oxide film 3 and CVD nitride film 4 is formed in the active region in the core circuit region and a thin two-layer structure 134 with oxide film 13 and CVD nitride film 14 is formed in the I/O circuit region.

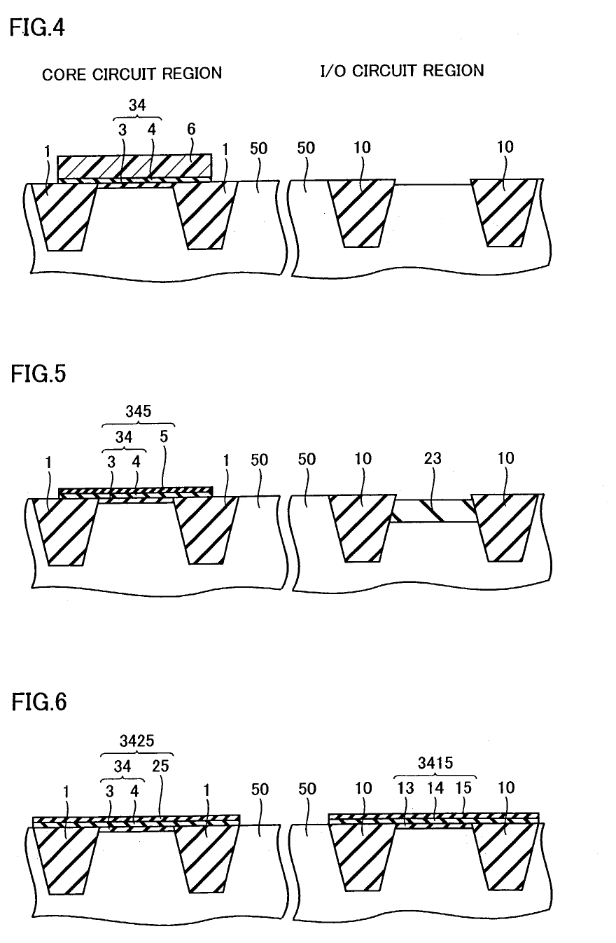

Then, as shown in FIG. 4, a photoresist film 6 is formed in the core circuit region and etching is performed selectively such that two-layer structure 134 of oxide film 13 and CVD nitride film 14 formed in the I/O circuit region is removed and two-layer structure 34 of oxide film 3 and nitride film 4 formed in the core circuit region is left.

Thereafter, as shown in FIG. 5, after performing a proper cleaning on the I/O circuit region, a thick gate insulating film is formed with a pure oxide film 23 free from nitrogen in the I/O circuit region by thermally oxidizing the surface of the active region of the silicon substrate as semiconductor substrate 50 in the I/O circuit region.

At that time, as shown in FIG. 5, a three-layer structure 345 having oxide film 3, CVD nitride film 4 and oxynitride film 5 is formed, as the surface of CVD nitride film 4 is oxidized in two-layer structure 34 of oxide film 3 and CVD nitride film 4 initially formed in the core circuit region. Therefore, a weak spot in CVD nitride film 4 is repaired, so that leak current is less likely to occur in the formed thin gate insulating film. In addition, since the surface of the active region in the I/O circuit region is oxidized to form a gate insulating film of pure oxide film 23, NBTI of the transistor in the I/O region is reduced.

Thermal oxidation is used to form the gate insulating film portion of the pure oxide film and also to repair the defect on the upper surface of the nitride film of the two-layer stack structure. Therefore, a single thermal oxidation process can reduce NBTI of the transistor in the second circuit region and also reduce the possibility of the leak current in the thin gate insulating film completed in the first circuit region. As a result, the semiconductor manufacturing process can be simplified.

Furthermore, as shown in FIG. 1, after polysilicon films are deposited on the core and I/O circuit regions, by photolithography and dry-etching, a gate electrode 7 is formed on the active region in the core circuit region and a gate electrode 17 is formed on the active region in the I/O circuit region.

In accordance with the method of manufacturing a semiconductor device in the present embodiment, CVD nitride film 4 in the second circuit region is removed after the two-layer structure of oxide film 3 and CVD nitride film 4 is formed in the second circuit region. Therefore, when CVD nitride film 4 is removed, oxide film 3 underlies CVD nitride film 4. As a result, in accordance with the method of manufacturing a semiconductor device in the present embodiment, defects are prevented on the surface of the active region in the second circuit region, as compared with a method including removing a CVD nitride film formed directly on the surface of the active region in the second circuit region.

(Second Embodiment)

The method of manufacturing a semiconductor device in accordance with a second embodiment will now be described. The method in the present embodiment differs from that in the first embodiment in the way of removing the two-layer structure of the oxide film and the CVD nitride film formed in the I/O circuit region and only leaving the two-layer structure of the oxide film and the CVD nitride film formed in the core circuit region. With reference to FIGS. 6 to 10, the method of manufacturing a semiconductor device in the present embodiment will be described below more specifically.

First, as shown in FIG. 3, two-layer structure 34 of oxide film 3 and CVD nitride film 4 is formed in the core circuit region and two-layer structure 134 of oxide film 13 and CVD nitride film 14 is formed in the I/O circuit region.

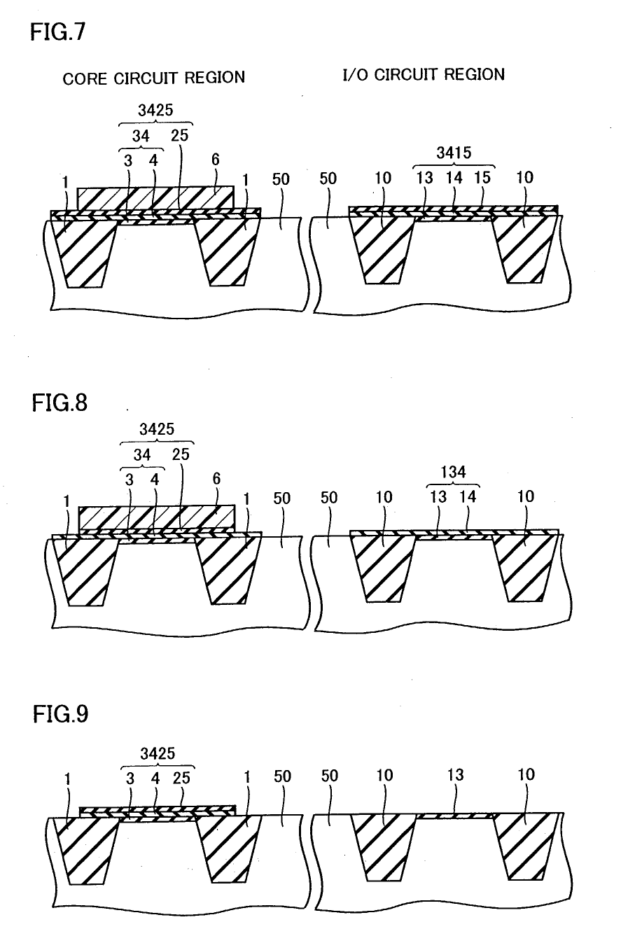

Thereafter, as shown in FIG. 6, for example, TEOS (Tetra Etyle Orthro Silicate) oxide films 25 and 15 are deposited on the active region in the core circuit region and the active region in the I/O circuit region to form three-layer structures 3425 and 3415, respectively. Then, as shown in FIG. 7, using photolithography, the active region in the core circuit region is covered with photoresist film 6.

Next, by wet-etching using hydrogen fluoride, using photoresist film 6 as a mask, TEOS oxide film 25 in the core circuit region and TEOS oxide film 15 in the I/O circuit region are etched. Since hydrogen fluoride is less likely to etch CVD nitride film 4 under TEOS oxide film 25 and CVD nitride film 14 under TEOS oxide film 15, as shown in FIG. 8, it is possible to selectively remove only TEOS oxide film 25 in a region not covered with photoresist film 6 in the core circuit region and TEOS oxide film 15 in the I/O circuit region.

After removing photoresist film 6, using TEOS oxide film 25 described above as a mask, hot phosphoric acid is used to etch CVD nitride film 4 in the core circuit region and CVD nitride film 14 in the I/O circuit region. Since hot phosphoric acid is less likely to etch TEOS oxide film 25 exposed in the core circuit region and oxide film 13 under nitride film 14 in the I/O circuit region, as shown in FIG. 9, it is possible to selectively remove only CVD nitride film 4 in a region not covered with TEOS oxide film 25 in the core circuit region and CVD nitride film 14 in the I/O circuit region, using hot phosphoric acid.

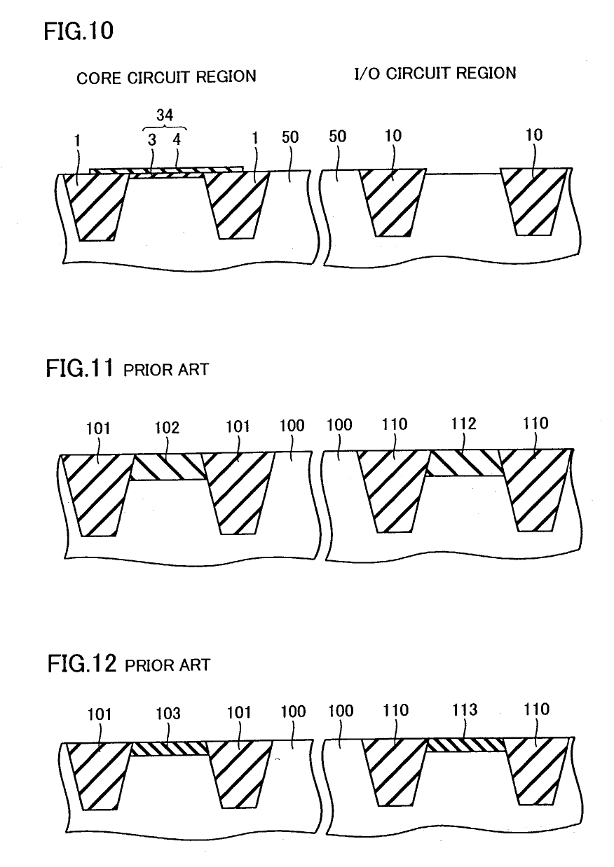

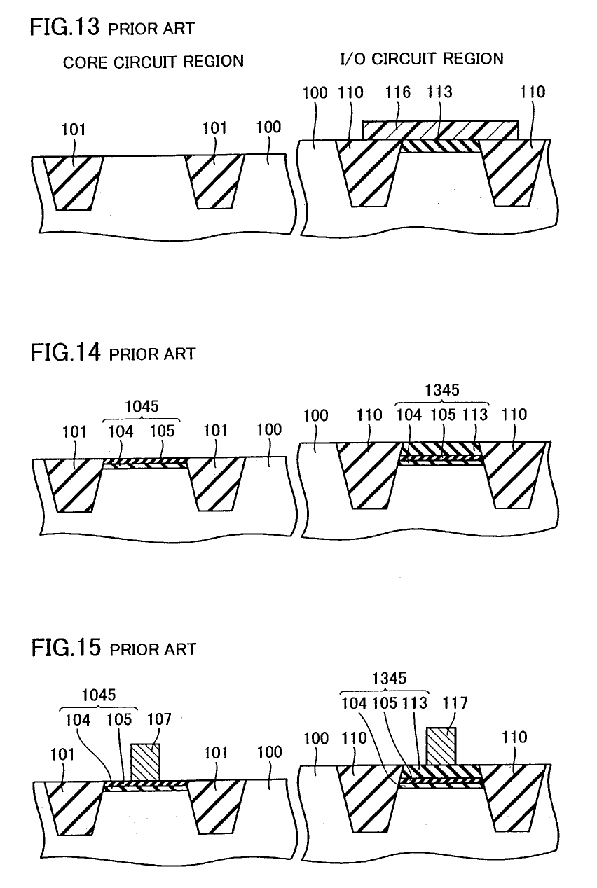

Then, as shown in FIG. 10, TEOS oxide film 25 in the core circuit region and oxide film 13 in the I/O circuit region are etched using hydrogen fluoride. It is noted that in the core circuit region only TEOS oxide film 25 can selectively be removed using nitride film 4 as a stopper, since hydrogen fluoride is less likely to etch CVD nitride film 4 under TEOS oxide film 25 in the core circuit region. In this manner, two-layer structure 34 of oxide film 3 and CVD nitride film 4 can be left in the core circuit region while three-layer structure 3415 of oxide film 13, CVD nitride film 14 and TEOS oxide film 15 formed in the I/O circuit region can entirely be removed.

Thereafter, similar to the method of manufacturing a semiconductor device in the first embodiment, as shown in FIG. 5, in the core circuit region, the surface of nitride film 4 of two-layer structure 34 of oxide film 3 and CVD nitride film 4 initially formed is oxidized so that three-layer structure 345 of oxide film 3, CVD nitride film 4 and oxynitride film 5 is formed. Therefore, the weak spot in CVD nitride film 4 is repaired, so that leak current in the formed thin gate insulating film is reduced. In addition, since a gate insulating film is formed with pure oxide film 23 resulting from oxidation of the surface of the active region in the I/O circuit region, NBTI of the transistor in the I/O region is reduced.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a semiconductor device including a dual oxide process forming a thin gate insulating film for a transistor included in a first circuit region and a thick gate insulating film for a transistor included in a second circuit region having a thickness larger than that of the thin gate insulating film on the same semiconductor substrate, wherein
in said first circuit region a transistor is formed including a thin gate insulating film having a two-layer structure including an oxide film and a CVD nitride film formed in this order on said semiconductor substrate, and in said second circuit region a transistor is formed having a drive voltage higher than that of the transistor in said first circuit region and including a thick gate insulating film having a pure oxide film with a thickness larger than that of said thin gate insulating film.

2. The method of manufacturing a semiconductor device according to claim 1, comprising:
a first step of forming said two-layer structure on an active region in said first circuit region while exposing an active region in said second circuit region; and
a second step of forming a gate insulating film portion of an oxide film, a CVD nitride film and an oxynitride film to form said thin gate insulating film by thermally oxidizing an upper surface of said CVD nitride film, and forming a gate insulating film portion of a pure oxide film to form said thick gate insulating film by thermally oxidizing the active region of said second circuit region.

3. The method of manufacturing a semiconductor device according to claim 2 wherein
said first step includes the steps of:
forming said two-layer structure on-each of the active regions in said first and second circuit regions: and
removing both layers of said two-layer structure on the active region in said second circuit region.

4. The method of manufacturing a semiconductor device according to claim 2, wherein
said first step includes the steps of:
forming a three-layer structure consisting of an oxide film, a CVD nitride film deposited on the oxide film, an oxide film deposited on the CVD nitride film on each of the active regions in said first and second circuit regions; and
removing only said oxide film of said three-layer structure in said first circuit region; and
removing all layers of said three-layer structure in said second circuit region.
